(19) United States
(12) Patent Application Publication
(10) Pub. No.: US 2025/0037923 A1
(43) Pub. Date: Jan. 30, 2025

(54) PACKAGE COMPRISING A SUBSTRATE WITH INDUCTORS AND A MAGNETIC LAYER

(71) Applicant: QUALCOMM Incorporated, San Diego, CA (US)

(72) Inventors: Kai LIU, Phoenix, AZ (US); Jui-Yi CHIU, Taichung City (TW); Jonghae KIM, San Diego, CA (US); Nosun PARK, San Diego, CA (US); Je-Hsiung LAN, San Diego, CA (US)

(21) Appl. No.: 18/360,570

(22) Filed: Jul. 27, 2023

(51) Int. Cl. H01F 27/28; H01F 41/04; H01L 21/48; H01L 23/00; H01L 23/498; H01L 25/18; H01L 27/01

(52) U.S. Cl. CPC H01F 27/2804; H01F 41/041; H01L 21/486; H01L 23/49827; H01L 24/16; H01L 25/18; H01L 27/01; H01F 27/24; H01F 2027/2809; H01L 2224/16227

(57) ABSTRACT

A package comprising an integrated device and a substrate coupled to the integrated device through a plurality of solder interconnects. The substrate comprises at least one magnetic layer, at least one dielectric layer; and a plurality of interconnects. The plurality of interconnects comprise a first set of interconnects that are configured to operate as a first inductor and a second set of interconnects that are configured to operate as a second inductor. The second inductor and the first inductor are configured to operate as inductively coupled inductors.

### FIELD

Various features relate to packages and substrates.

### BACKGROUND

Packages can include a substrate, an integrated device and an inductor. The substrate may include a plurality of interconnects. Inductors help in the proper operation of the package and any integrated devices that may be electrically coupled to inductors. There is an ongoing need to provide smaller packages with improved performances, such as packages with improved inductor performance.

### SUMMARY

Various features relate to packages and substrates.

One example provides a package comprising an integrated device and a substrate coupled to the integrated device through a plurality of solder interconnects. The substrate comprises at least one magnetic layer; at least one dielectric layer; and a plurality of interconnects. The plurality of interconnects comprise a first set of interconnects that are configured to operate as a first inductor and a second set of interconnects that are configured to operate as a second inductor. The second inductor and the first inductor are configured to operate as inductively coupled inductors.

Another example provides a substrate comprising at least one magnetic layer; at least one dielectric layer; and a plurality of interconnects. The plurality of interconnects comprises a first set of interconnects that are configured to operate as a first inductor and a second set of interconnects that are configured to operate as a second inductor. The second inductor and the first inductor are configured to operate as inductively coupled inductors.

Another example provides a method for fabricating a substrate. The method provides at least one magnetic layer. The method provides at least one dielectric layer. The method forms a plurality of interconnects. The plurality of interconnects comprises a first set of interconnects that are configured to operate as a first inductor; and a second set of interconnects that are configured to operate as a second inductor, wherein the second inductor and the first inductor are configured to operate as inductively coupled inductors.

### BRIEF DESCRIPTION OF THE DRAWINGS

Various features, nature and advantages may become apparent from the detailed description set forth below when taken in conjunction with the drawings in which like reference characters identify correspondingly throughout.

FIG. 1 illustrates an exemplary profile view of a substrate with inductors and at least one magnetic layer.

FIG. 2 illustrates an exemplary profile view of a substrate with inductors and at least one magnetic layer.

FIG. 3 illustrates an exemplary profile view of a substrate with inductors and at least one magnetic layer.

FIG. 4 illustrates an exemplary profile view of a package that includes a substrate with inductors and at least one magnetic layer.

FIG. 5 illustrates an exemplary graph of various inductor properties for a substrate that includes inductors and at least one magnetic layer.

FIG. 6 illustrates an exemplary graph of various inductor properties for a substrate that includes inductors and at least one magnetic layer.

FIG. 7 illustrates an exemplary graph of various inductor properties for a substrate that includes inductors and at least one magnetic layer.

FIGS. 8A-8C illustrate an exemplary sequence for fabricating a substrate that includes inductors and at least one magnetic layer.

FIG. 9 illustrates an exemplary sequence for fabricating a substrate that includes inductors and at least one magnetic layer.

FIGS. 10A-10C illustrate an exemplary sequence for fabricating a substrate that includes inductors and at least one magnetic layer.

FIG. 11 illustrates an exemplary sequence for fabricating a substrate that includes inductors and at least one magnetic layer.

FIG. 12 illustrates various electronic devices that may integrate a die, an electronic circuit, an integrated device, an integrated passive device (IPD), a passive component, a package, and/or a device package described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown in block diagrams in order to avoid obscuring the aspects in unnecessary detail. In other instances, well-known circuits, structures and techniques may not be shown in detail in order not to obscure the aspects of the disclosure.

The present disclosure describes a package comprising an integrated device and a substrate coupled to the integrated device through at least a plurality of solder interconnects. The substrate comprises at least one magnetic layer; at least one dielectric layer; and a plurality of interconnects. The plurality of interconnects comprises a first set of interconnects that are configured to operate as a first inductor and a second set of interconnects that are configured to operate as a second inductor. The second inductor and the first inductor are configured to operate as inductively coupled inductors. In some implementations, the first inductor is configured to induce a current in the second inductor, and vice versa. The use of a magnetic layer helps improve inductive properties of the first inductor and/or the second inductor, such as the inductance and/or the Q factor for the first inductor and/or the second inductor. This may allow for smaller sized inductors that have an inductance and/or Q factors that are similar or greater than inductances and/or Q factors of relatively larger inductors. Smaller inductors can be implemented in smaller devices, which can help improve the overall performance of the smaller devices.

### Exemplary Package With a Substrate Comprising a Magnetic Layer

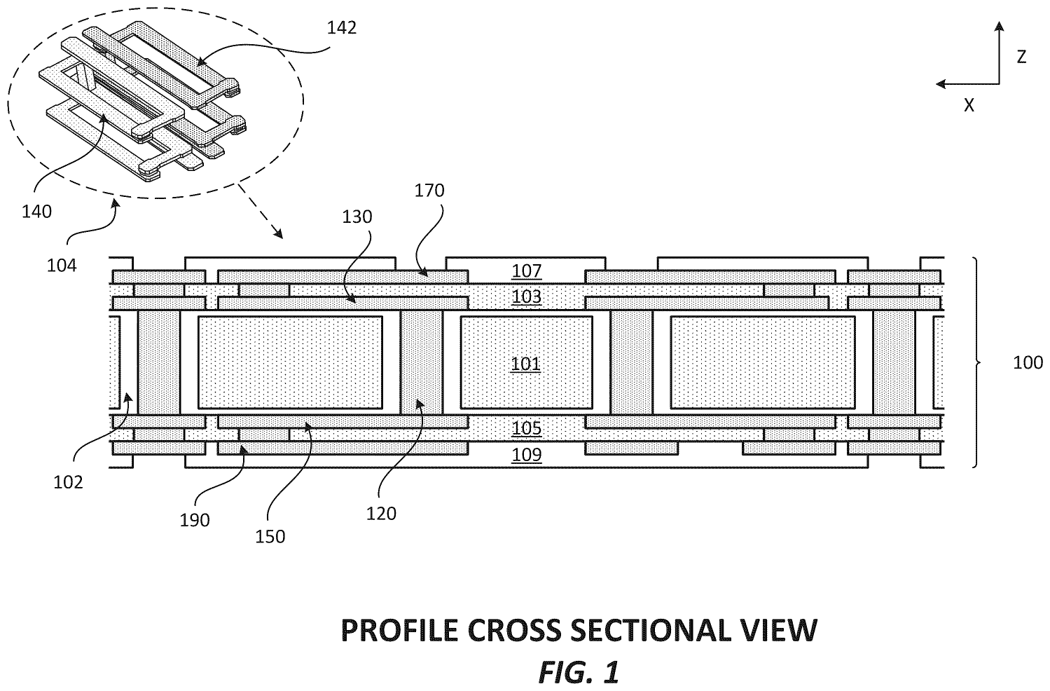

FIG. 1 illustrates a profile view of a substrate 100 that includes inductors and at least one magnetic material. The substrate 100 may be part of a package that includes an integrated device. The substrate 100 includes a magnetic layer 101, a magnetic layer 103, a magnetic layer 105, a dielectric layer 102, a solder resist layer 107, a solder resist layer 109, a plurality of via interconnects 120, a plurality of interconnects 130, a plurality of interconnects 150, a plurality of interconnects 170 and a plurality of interconnects 190.

As will be further described below, a first set of interconnects from interconnects of the substrate 100 are configured to operate as a first inductor, and a second set of interconnects from interconnects of the substrate 100 are configured to operate as a second inductor, where the first inductor and the second inductor are configured to operate as inductively coupled inductors. For example, the first inductor may be configured to induce a current in the second inductor. Similarly, the second inductor may be configured to induce a current in the first inductor. In some implementations, the first inductor may be configured to be inductively coupled to the second inductor. In some implementations, the second inductor may be configured to be inductively coupled to the first inductor. In some implementations, inductive coupling may mean inductive magnetic coupling.

The magnetic layer 101 may be a first magnetic layer and may include a first magnetic material. The dielectric layer 102 may be coupled to a first surface (e.g., top surface) of the magnetic layer 101 and a second surface (e.g., bottom surface) of the magnetic layer 101. Thus, the dielectric layer 102 may be located above the first surface of the magnetic layer 101, and below the second surface of the magnetic layer 101. The magnetic layer 101 may be surrounded by the dielectric layer 102. For example, the dielectric layer 102 may at least partially and laterally surround part of the magnetic layer 101. In some implementations, the magnetic layer 101 may be considered to be located in the dielectric layer 102.

The plurality of via interconnects 120 are located in the dielectric layer 102. The plurality of via interconnects 120 may extend through the thickness of the dielectric layer 102. The plurality of interconnects 130 may be coupled to the plurality of via interconnects 120. The plurality of interconnects 130 may be coupled to a first surface (e.g., top surface) of the dielectric layer 102. The plurality of interconnects 130 may be located in the magnetic layer 103. The plurality of interconnects 170 are coupled to the plurality of interconnects 130. A solder resist layer 107 may touch the plurality of interconnects 170 and the magnetic layer 103. The solder resist layer 107 may include openings that expose portions of the plurality of interconnects 170.

The plurality of interconnects 150 may be coupled to the plurality of via interconnects 120. The plurality of interconnects 150 may be coupled to a second surface (e.g., bottom surface) of the dielectric layer 102. The plurality of interconnects 150 may be located in the magnetic layer 105. The plurality of interconnects 190 are coupled to the plurality of interconnects 150. A solder resist layer 109 may touch the plurality of interconnects 190 and the magnetic layer 105. The solder resist layer 109 may include openings that expose portions of the plurality of interconnects 190.

In some implementations, the magnetic layer 103 may be a second magnetic layer, and the magnetic layer 105 may be a third magnetic layer. In some implementations, the magnetic layer 105 may be a second magnetic layer, and the magnetic layer 103 may be a third magnetic layer. The magnetic layer 103 may be the same, similar or different from the magnetic layer 101. Thus, the magnetic layer 103 may have the same, similar or different magnetic properties from the magnetic layer 101. The magnetic layer 103 may be the same, similar or different from the magnetic layer 105. Thus, the magnetic layer 103 may have the same, similar or different magnetic properties from the magnetic layer 105. The magnetic layer 105 may be the same, similar or different from the magnetic layer 101. Thus, the magnetic layer 105 may have the same, similar or different magnetic properties from the magnetic layer 101.

A magnetic layer includes an insulating layer, a dielectric layer and/or a non-electrical conducting material (e.g., material that does not electrically conduct). A magnetic layer may be both a dielectric material and a magnetic material. Thus, a magnetic layer may have both dielectric properties and magnetic properties. A magnetic layer may include one or more materials. A magnetic layer has a permeability value that is greater than 1 (e.g., about 10 or greater, range of 6-20). The magnetic layer may have different permeability values at different frequencies. The permeability value of a magnetic material and/or a magnetic layer, as described in the disclosure is a relative permeability value that is defined as a ratio of the permeability of a material to the permeability of free space. Thus, the permeability values that are described for the magnetic materials and/or magnetic layers that are illustrated and/or described in the disclosure may represent a relative permeability value that is relative to a defined permeability value (e.g., reference permeability value) of free space. In some implementations, free space may be defined to have a defined permeability value of μ₀=4π×10⁻⁷ H/m (Henry per meter). A material that has a relative permeability value that is greater than 1 may be considered to be a magnetic material. Similarly, a material layer that has a relative permeability value that is greater than 1 may be considered to be a magnetic layer. A magnetic layer may include a magnetic loss tangent value that is in a range of about 0.01-0.75. For example, the at least one magnetic layer may include a magnetic loss tangent value that is in a range of about 0.01-0.75 for frequencies up to 100 MHz. A magnetic layer may include various magnetic materials. For example, a magnetic layer may include Ajinomoto Magnetic Film (AMF). A magnetic layer may be configured to improve the inductance and/or quality factor of an inductor at low frequencies, that is located in and/or surrounded by the at least one magnetic layer. With improved inductor performance, smaller and more compact inductors may be formed in a substrate and/or a package.

FIG. 1 illustrates coupled inductors 104. The coupled inductors 104 may be inductively coupled inductors. The coupled inductors 104 includes an inductor 140 and an inductor 142. The inductor 140 may be a first inductor and the inductor 142 may be a second inductor. The inductor 140 may be configured to be inductively coupled to the inductor 142, and vice versa. The inductor 140 may be configured to induce a current in the inductor 142, and vice versa. The inductor 140 is close enough/adjacent enough to the inductor 142, for the inductor 140 to induce a current in the inductor 142, and vice versa. It is noted that the inductor 140 and the inductor 142 conceptually represent examples of inductors. Different implementations may use inductors with different designs and/or sizes (e.g., interconnects with different sizes and/or interconnects with different thicknesses).

In some implementations, the inductor 140 may be defined from a first set of interconnects from interconnects from the substrate 100. For example, the inductor 140 may be defined from a first set of interconnects from (i) the plurality of interconnects 170, (ii) the plurality of interconnects 130, (iii) the plurality of via interconnects 120, (iv) the plurality of interconnects 150, and/or (v) the plurality of interconnects 190 from the substrate 100.

In some implementations, the inductor 142 may be defined from a second set of interconnects from interconnects from the substrate 100. For example, the inductor 142 may be defined from a second set of interconnects from (i) the plurality of interconnects 170, (ii) the plurality of interconnects 130, (iii) the plurality of via interconnects 120, (iv) the plurality of interconnects 150, and/or (v) the plurality of interconnects 190 from the substrate 100.

The various magnetic layers of the substrate 100 are located in and around the interconnects that define the inductor 140 and/or the inductor 142, which helps improve the inductive properties of the inductor 140 and/or the inductor 142, such as the Q factor of the inductor 140 and/or inductor 142. For example, a magnetic layer may be located within and/or around (i) the windings of the inductor 140 and/or (ii) the windings of the inductor 142. One or more magnetic layers may be located above and/or below the inductor 140 and/or the inductor 142.

As mentioned above, the use of at least one magnetic layer helps improve inductive properties of the first inductor and/or the second inductor, such as the inductance and/or the Q factor for the first inductor and/or the second inductor. This may allow for smaller sized inductors that have an inductance and/or Q factors that are similar or greater than inductances and/or Q factors of relatively larger inductors. Smaller inductors can be implemented in smaller devices, which can help improve the overall performance of the smaller devices.

In some implementations, some of the interconnects from (i) the plurality of interconnects 170, (ii) the plurality of interconnects 130, (iii) the plurality of via interconnects 120, (iv) the plurality of interconnects 150, and/or (v) the plurality of interconnects 190 may be used as one or more electrical paths within the substrate 100 for power.

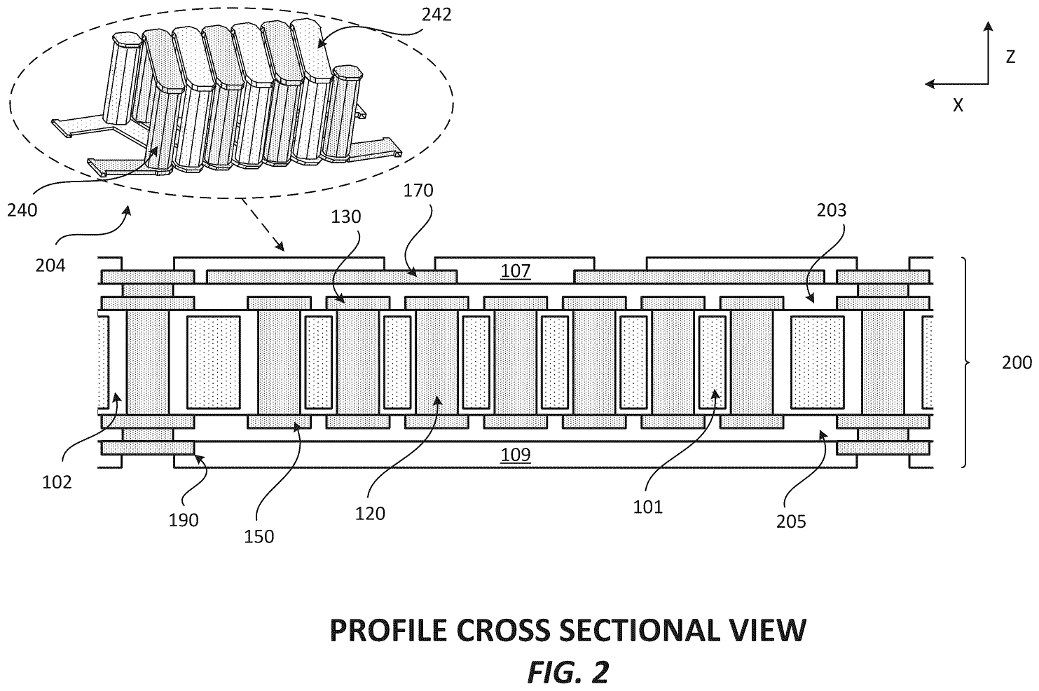

FIG. 2 illustrates a profile view of a substrate 200 that includes inductors and at least one magnetic material. The substrate 200 may be part of a package that includes an integrated device. The substrate 200 includes a magnetic layer 101, a dielectric layer 102, a dielectric layer 203, a dielectric layer 205, a solder resist layer 107, a solder resist layer 109, a plurality of via interconnects 120, a plurality of interconnects 130, a plurality of interconnects 150, a plurality of interconnects 170 and a plurality of interconnects 190. The substrate 200 may be similar to the substrate 100. However, the substrate 200 includes a different configuration of the magnetic layers and a different design in the inductors from the substrate 100.

The magnetic layer 101 may be a first magnetic layer and may include a first magnetic material. The dielectric layer 102 may be coupled to a first surface (e.g., top surface) of the magnetic layer 101 and a second surface (e.g., bottom surface) of the magnetic layer 101. Thus, the dielectric layer 102 may be located above the first surface of the magnetic layer 101, and below the second surface of the magnetic layer 101. The magnetic layer 101 may be surrounded by the dielectric layer 102. For example, the dielectric layer 102 may at least partially and laterally surround part of the magnetic layer 101. In some implementations, the magnetic layer 101 may be considered to be located in the dielectric layer 102.

The plurality of via interconnects 120 are located in the dielectric layer 102. The plurality of via interconnects 120 may extend through the thickness of the dielectric layer 102. The plurality of interconnects 130 may be coupled to the plurality of via interconnects 120. The plurality of interconnects 130 may be coupled to a surface of the dielectric layer 102. The plurality of interconnects 130 may be located in the dielectric layer 203. The plurality of interconnects 170 are coupled to the plurality of interconnects 130. A solder resist layer 107 may touch the plurality of interconnects 170 and the dielectric layer 203. The solder resist layer 107 may include openings that expose portions of the plurality of interconnects 170.

The plurality of interconnects 150 may be coupled to the plurality of via interconnects 120. The plurality of interconnects 150 may be coupled to a surface of the dielectric layer 102. The plurality of interconnects 150 may be located in the dielectric layer 205. The plurality of interconnects 190 are coupled to the plurality of interconnects 150. A solder resist layer 109 may touch the plurality of interconnects 190 and the dielectric layer 205. The solder resist layer 109 may include openings that expose portions of the plurality of interconnects 190.

FIG. 2 illustrates coupled inductors 204. The coupled inductors 204 may be inductively coupled inductors. The coupled inductors 204 include an inductor 240 and an inductor 242. The inductor 240 may be a first inductor and the inductor 242 may be a second inductor. The inductor 240 may be configured to be inductively coupled to the inductor 242, and vice versa. The inductor 240 may be configured to induce a current in the inductor 242, and vice versa. The inductor 240 is close enough/adjacent enough to the inductor 242, for the inductor 240 to induce a current in the inductor 242, and vice versa. The inductor 240 and the inductor 242 may be intertwined. For example, the inductor 240 may be a first solenoid inductor, and the inductor 242 may be a second solenoid inductor. The first solenoid inductor may be intertwined with the second inductor. It is noted that the inductor 240 and the inductor 242 conceptually represent examples of inductors. Different implementations may use inductors with different designs and/or sizes (e.g., interconnects with different sizes and/or interconnects with different thicknesses).

In some implementations, the inductor 240 may be defined from a first set of interconnects from interconnects from the substrate 200. For example, the inductor 240 may be defined from a first set of interconnects from (i) the plurality of interconnects 170, (ii) the plurality of interconnects 130, (iii) the plurality of via interconnects 120, (iv) the plurality of interconnects 150, and/or (v) the plurality of interconnects 190 from the substrate 200.

In some implementations, the inductor 242 may be defined from a second set of interconnects from interconnects from the substrate 200. For example, the inductor 242 may be defined from a second set of interconnects from (i) the plurality of interconnects 170, (ii) the plurality of interconnects 130, (iii) the plurality of via interconnects 120, (iv) the plurality of interconnects 150, and/or (v) the plurality of interconnects 190 from the substrate 200.

The magnetic layer 101 of the substrate 200 is located in and around the interconnects that define the inductor 240 and/or the inductor 242, which helps improve the inductive properties of the inductor 240 and/or the inductor 242, such as the inductances and/or the Q factors of the inductor 240 and/or inductor 242. For example, a magnetic layer may be located within and/or around (i) the windings of the inductor 240 and/or (ii) the windings of the inductor 242. One or more magnetic layers may be located above and/or below the windings of the inductor 240 and/or the windings of the inductor 242.

In some implementations, some of the interconnects from (i) the plurality of interconnects 170, (ii) the plurality of interconnects 130, (iii) the plurality of via interconnects 120, (iv) the plurality of interconnects 150, and/or (v) the plurality of interconnects 190 may be used as one or more electrical paths within the substrate 200 for power.

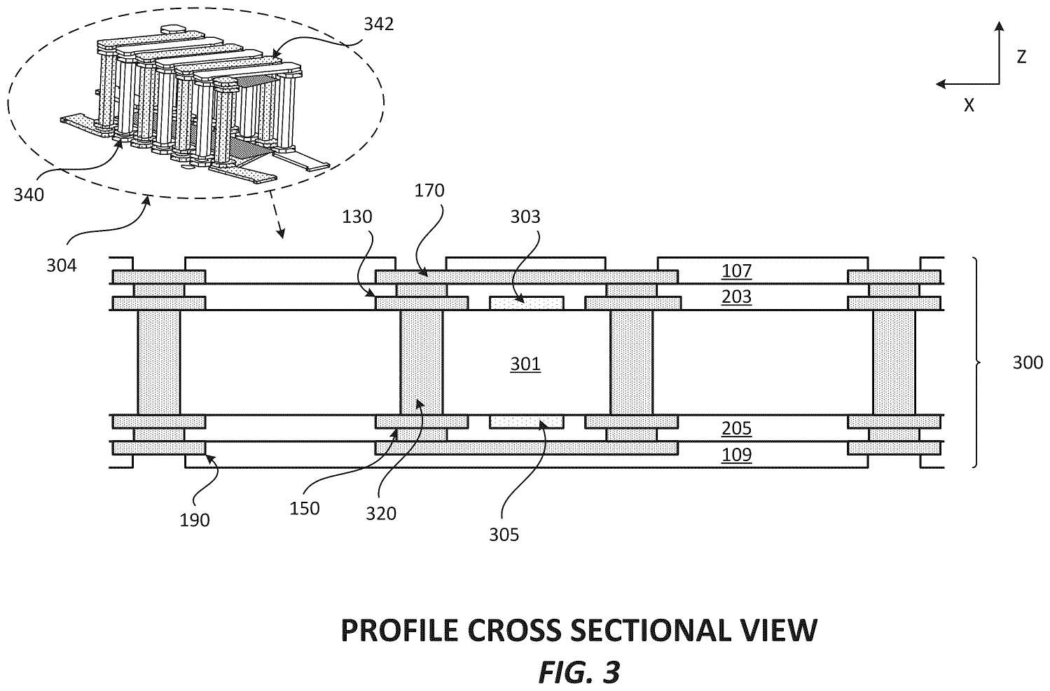

FIG. 3 illustrates a profile view of a substrate 300 that includes inductors and at least one magnetic material. The substrate 300 may be part of a package that includes an integrated device. The substrate 300 includes a core layer 301, a magnetic layer 303, a magnetic layer 305, a dielectric layer 102, a dielectric layer 203, a dielectric layer 205, a solder resist layer 107, a solder resist layer 109, a plurality of via interconnects 310, a plurality of interconnects 130, a plurality of interconnects 150, a plurality of interconnects 170 and a plurality of interconnects 190.

The plurality of via interconnects 310 are located in the core layer 301. The plurality of via interconnects 120 may extend through the thickness of the core layer 301. The plurality of interconnects 130 may be coupled to the plurality of via interconnects 120. The plurality of interconnects 130 may be coupled to a first surface (e.g., top surface) of the core layer 301. The plurality of interconnects 130 may be located in the dielectric layer 203. The plurality of interconnects 170 are coupled to the plurality of interconnects 130. A solder resist layer 107 may touch the plurality of interconnects 170 and the dielectric layer 203. The solder resist layer 107 may include openings that expose portions of the plurality of interconnects 170. A magnetic layer 303 may be coupled to a surface (e.g., first surface) of the core layer 301. The magnetic layer 303 may be located in the dielectric layer 203.

The plurality of interconnects 150 may be coupled to the plurality of via interconnects 320. The plurality of interconnects 150 may be coupled to a second surface (e.g., bottom surface) of the core layer 301. The plurality of interconnects 150 may be located in the dielectric layer 205. The plurality of interconnects 190 are coupled to the plurality of interconnects 150. A solder resist layer 109 may touch the plurality of interconnects 190 and the dielectric layer 205. The solder resist layer 109 may include openings that expose portions of the plurality of interconnects 190. A magnetic layer 305 may be coupled to a surface (e.g., second surface) of the core layer 301. The magnetic layer 305 may be located in the dielectric layer 205.

FIG. 3 illustrates coupled inductors 304. The coupled inductors 304 may be inductively coupled inductors. The coupled inductors 304 include an inductor 340 and an inductor 342. The inductor 340 may be a first inductor and the inductor 342 may be a second inductor. The inductor 340 may be configured to be inductively coupled to the inductor 342, and vice versa. The inductor 340 may be configured to induce a current in the inductor 342, and vice versa. The inductor 340 is close enough/adjacent enough to the inductor 342, for the inductor 340 to induce a current in the inductor 342, and vice versa. The inductor 340 and the inductor 342 may be intertwined. For example, the inductor 340 may be a first solenoid inductor, and the inductor 342 may be a second solenoid inductor. The first solenoid inductor may be intertwined with the second inductor. It is noted that the inductor 340 and the inductor 342 conceptually represent examples of inductors. Different implementations may use inductors with different designs and/or sizes (e.g., interconnects with different sizes and/or different thicknesses).

In some implementations, the inductor 340 may be defined from a first set of interconnects from interconnects from the substrate 300. For example, the inductor 340 may be defined from a first set of interconnects from (i) the plurality of interconnects 170, (ii) the plurality of interconnects 130, (iii) the plurality of via interconnects 320, (iv) the plurality of interconnects 150, and/or (v) the plurality of interconnects 190 from the substrate 300.

In some implementations, the inductor 342 may be defined from a second set of interconnects from interconnects from the substrate 300. For example, the inductor 342 may be defined from a second set of interconnects from (i) the plurality of interconnects 170, (ii) the plurality of interconnects 130, (iii) the plurality of via interconnects 120, (iv) the plurality of interconnects 150, and/or (v) the plurality of interconnects 190 from the substrate 300.

The magnetic layer 303 and/or the magnetic layer 305 may be located in and around the interconnects that define the inductor 340 and/or the inductor 342, which helps improve the inductive properties of the inductor 340 and/or the inductor 342, such as the inductances and/or the Q factors of the inductor 340 and/or inductor 342. For example, a magnetic layer may be located within and/or around (i) the windings of the inductor 340 and/or (ii) the windings of the inductor 342. One or more magnetic layers may be located above and/or below the windings of the inductor 340 and/or the windings of the inductor 342.

In some implementations, some of the interconnects from (i) the plurality of interconnects 170, (ii) the plurality of interconnects 130, (iii) the plurality of via interconnects 320, (iv) the plurality of interconnects 150, and/or (v) the plurality of interconnects 190 may be used as one or more electrical paths within the substrate 300 for power.

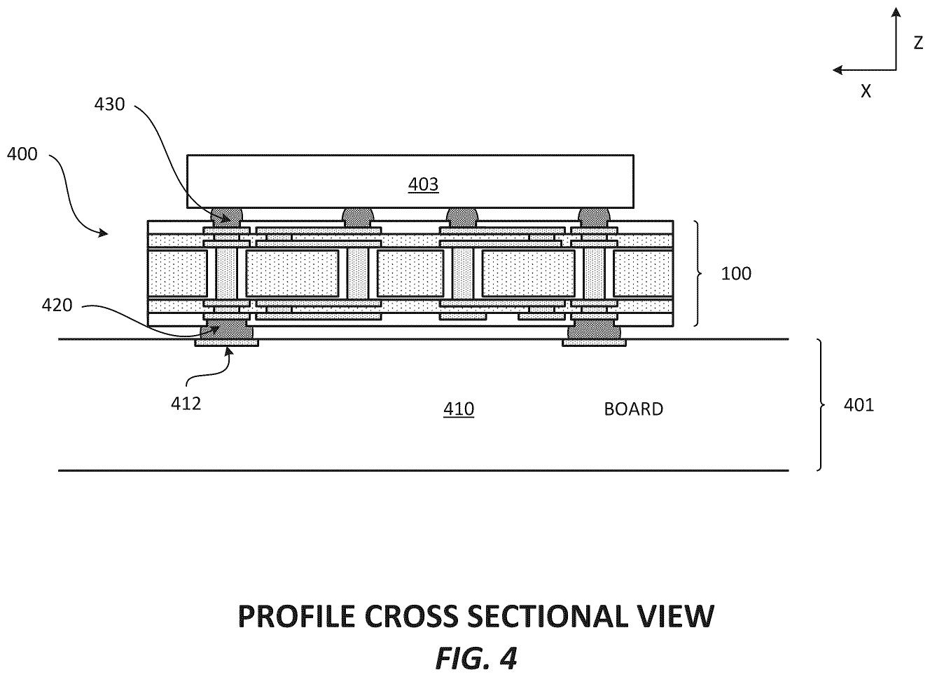

FIG. 4 illustrates a package 400 that includes a substrate 100 and an integrated device 403. The package 400 is coupled to a board 401 through a plurality of solder interconnects 420. The board 401 includes at least one board dielectric layer 410 and a plurality of board interconnects 412. The integrated device 403 is coupled to the substrate 100 through at least a plurality of solder interconnects 430. In some implementations, the integrated device 403 may be coupled to the substrate 100 through the plurality of solder interconnects 430 and/or a plurality of pillar interconnects (not shown).

As mentioned above, the substrate 100 includes at least two inductors. The integrated device 403 may be configured to be electrically coupled to the at least two inductors of the substrate 100. The integrated device 403 may be configured as a power management integrated circuit (PMIC).

The integrated device 403 may be configured to be electrically coupled to the board 401 through (i) solder interconnects from the plurality of solder interconnects 430, (ii) interconnects from the plurality of interconnects from the substrate 100, and (iii) solder interconnects from the plurality of solder interconnects 420.

The size of the substrate 100 relative to the integrated device 403 may be different with different implementations. In some implementations, the lateral size of the substrate 100 may be bigger than the lateral size of the integrated device 403. In some implementations, the substrate 100 may include more than two inductors. For example, a second integrated device may be coupled to the substrate 100, and the second integrated device may be configured to be electrically coupled to a different set of inductors. For example, the integrated device 403 may be configured to be electrically coupled to a first inductor and a second inductor of the substrate 100, and a second integrated device (not shown) may be configured to be electrically coupled to a third inductor (not shown) and a fourth inductor (not shown). The third inductor and the fourth inductor may be coupled inductors.

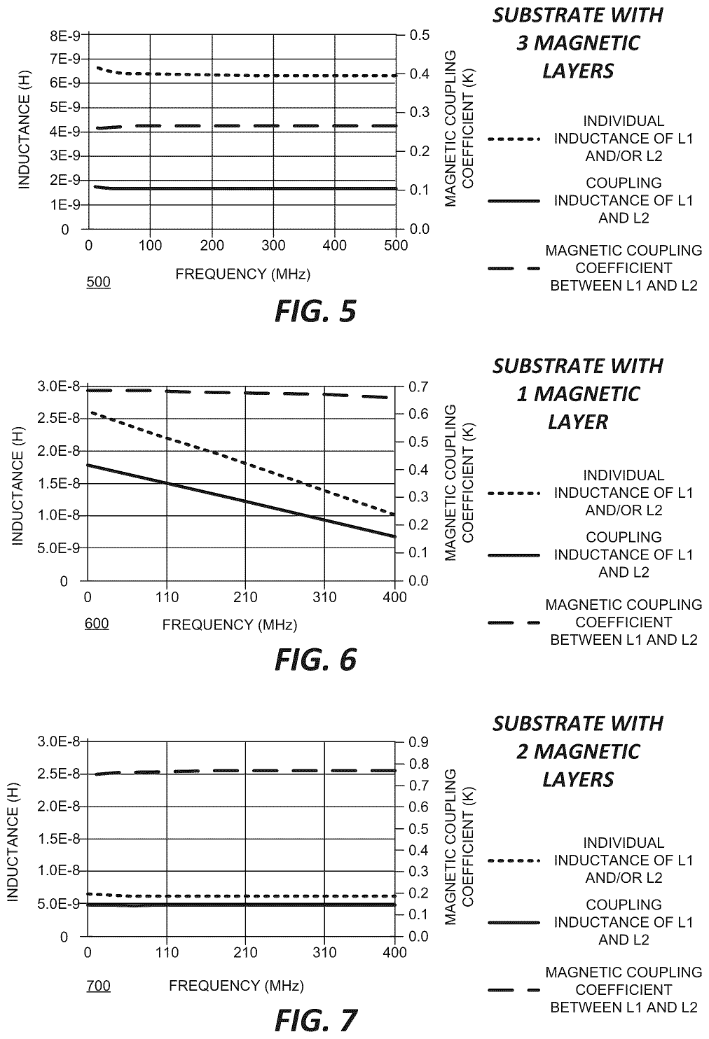

FIGS. 5-7 illustrate exemplary graphs of various inductive properties for various substrates with various configuration of at least one magnetic layer. FIG. 5 illustrates an exemplary graph 500 that illustrates the inductances, the coupling inductance and the magnetic coupling coefficient of the inductors of the substrate 100. As shown in FIG. 5, the magnetic coupling coefficient (K) between the inductor 140 and the inductor 142 is about 26%. FIG. 6 illustrates an exemplary graph 600 that illustrates the inductances, the coupling inductance and the magnetic coupling of the inductors of the substrate 200. As shown in FIG. 6, the magnetic coupling coefficient (K) between the inductor 240 and the inductor 242 is about 68%. FIG. 7 illustrates an exemplary graph 700 that illustrates the inductances, the coupling inductance and the magnetic coupling of the inductors of the substrate 300. As shown in FIG. 7, the magnetic coupling coefficient (K) between the inductor 340 and the inductor 342 is about 76%. A higher magnetic coupling coefficient (K) means a better transfer of energy between inductors. The coupling inductance between two inductors may be related to the magnetic coupling coefficient (K). A larger coupling inductance may mean a larger coupling coefficient (K) for a pair of inductors. It is noted that inductances, coupling inductances and magnetic coupling coefficients are exemplary and different implementations and/or configuration of the substrate and/or the inductors may provide different inductances, coupling inductances and/or magnetic coupling coefficients.

An integrated device may include a die (e.g., semiconductor bare die). The integrated device may include a power management integrated circuit (PMIC). The integrated device may include an application processor. The integrated device may include a modem. The integrated device may include a radio frequency (RF) device, a passive device, a filter, a capacitor, an inductor, an antenna, a transmitter, a receiver, a gallium arsenide (GaAs) based integrated device, a surface acoustic wave (SAW) filter, a bulk acoustic wave (BAW) filter, a light emitting diode (LED) integrated device, a silicon (Si) based integrated device, a silicon carbide (SiC) based integrated device, a memory, power management processor, and/or combinations thereof. An integrated device may include at least one electronic circuit (e.g., first electronic circuit, second electronic circuit, etc. . . . ). An integrated device may include transistors. An integrated device may be an example of an electrical component and/or electrical device. In some implementations, an integrated device may include a chiplet. A chiplet may be fabricated using a process that provides better yields compared to other processes that are used to fabricate other types of integrated devices, which can lower the overall cost of fabricating a chiplet. Different chiplets may have different sizes and/or shapes. Different chiplets may be configured to provide different functions. Different chiplets may have different interconnect densities (e.g., interconnects with different width and/or spacing). In some implementations, several chiplets may be used to perform the functionalities of one or more chips (e.g., one more integrated devices). Using several chiplets that perform several functions may reduce the overall cost of a package relative to using a single chip to perform all of the functions of a package.

### Exemplary Sequence for Fabricating a Substrate With a Magnetic Layer

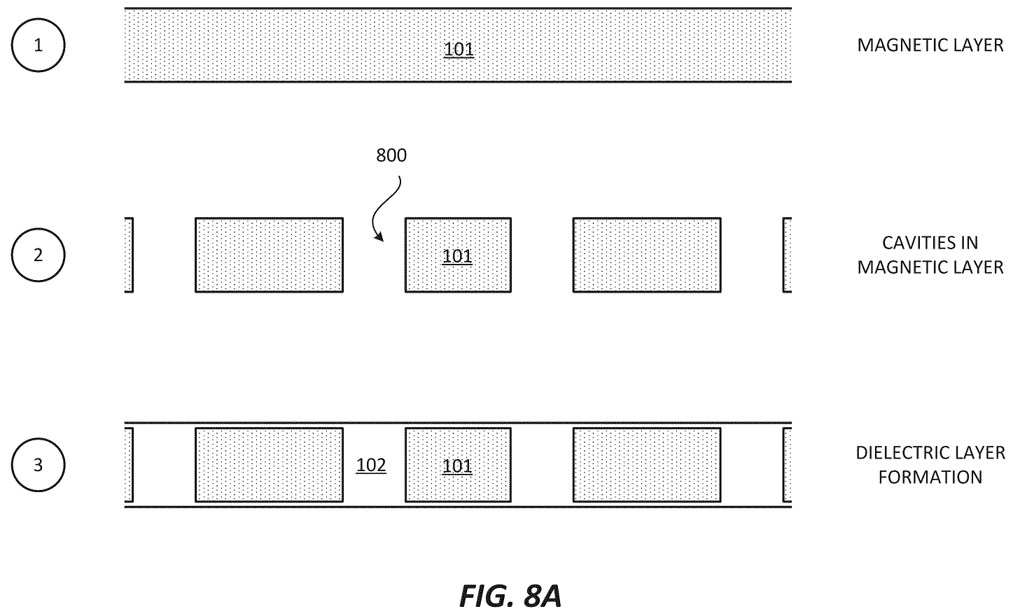

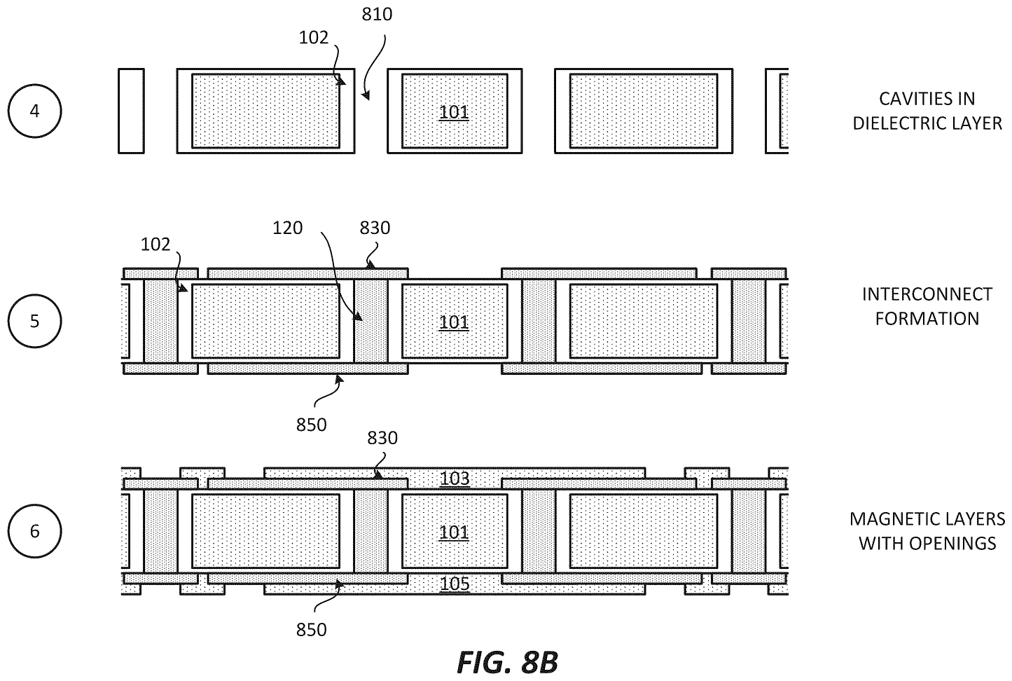

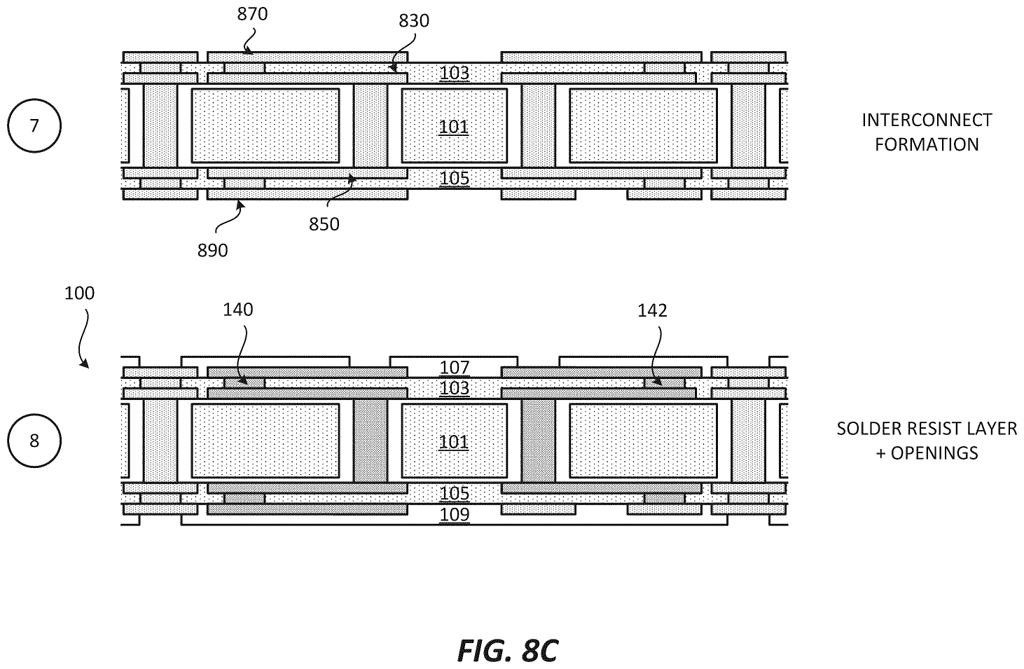

FIGS. 8A-8C illustrate an exemplary sequence for providing or fabricating a substrate with inductors and at least one magnetic layer. In some implementations, the sequence of FIGS. 8A-8C may be used to provide or fabricate any of the substrates described in the disclosure. In some implementations, the sequence of FIGS. 8A-8C may be used to provide or fabricate the substrate 100 described in the disclosure.

It should be noted that the sequence of FIGS. 8A-8C may combine one or more stages in order to simplify and/or clarify the sequence for providing or fabricating a substrate. In some implementations, the order of the processes may be changed or modified. In some implementations, one or more of processes may be replaced or substituted without departing from the spirit of the disclosure. Different implementations may fabricate a substrate differently.

Stage 1, as shown in FIG. 8A, illustrates a state after a magnetic layer 101 is provided. Different implementations may provide different types of a magnetic layer.

Stage 2 illustrates a state after a plurality of cavities 800 are formed through the magnetic layer 101. A laser process (e.g., laser ablation process) may be used to form the plurality of cavities 800 in the magnetic layer 101. However, different implementations may use different processes to form the plurality of cavities 800. The plurality of cavities 800 may extend through the thickness of the magnetic layer 101.

Stage 3 illustrates a state after a dielectric layer 102 is formed. The dielectric layer 102 may be formed in the plurality of cavities 800 of the magnetic layer 101. The dielectric layer 102 may also be formed and coupled to (i) a first surface (e.g., top surface) of the magnetic layer 101 and/or (ii) a second surface (e.g., bottom surface) of the magnetic layer 101. A deposition process and/or a lamination process may be used to form the dielectric layer 102. In some implementations, the dielectric layer 102 may include a polymer. In some implementations, the dielectric layer 102 may include Ajinomoto Build-up Film (ABF). In some implementations, the dielectric layer 102 may include prepreg.

Stage 4, as shown in FIG. 8B, illustrates a state after a plurality of cavities 810 are formed through the dielectric layer 102. A laser process (e.g., laser ablation) may be used to form the plurality of cavities 810 in the dielectric layer 102. However, different implementations may use different processes to form the plurality of cavities 810. The plurality of cavities 810 may extend through the thickness of the dielectric layer 102.

Stage 5 illustrates a state after a plurality of via interconnects 120 are formed in the plurality of cavities 810. The plurality of via interconnects 120 may be considered to be located in the dielectric layer 102 and/or located in at least part of the plurality of cavities 800 of the magnetic layer 101. Stage 5 also illustrates a plurality of interconnects 830 that are formed and coupled to a first surface (e.g., top surface) of the dielectric layer 102. The plurality of interconnects 830 are coupled to the plurality of via interconnects 120. Stage 5 also illustrates a plurality of interconnects 850 that are formed and coupled to a second surface (e.g., bottom surface) of the dielectric layer 102. The plurality of interconnects 850 are coupled to the plurality of via interconnects 120. A plating process and a patterning process may be used to form the plurality of via interconnects 120, the plurality of interconnects 830 and/or the plurality of interconnects 850.

Stage 6 illustrates a state after the magnetic layer 103 and the magnetic layer 105 are formed. The magnetic layer 103 may be formed and coupled to the first surface of the dielectric layer 102. The magnetic layer 103 may be formed such that at least part of the plurality of interconnects 830 may be located in at least part of the magnetic layer 103. The magnetic layer 103 may include a plurality of openings. A deposition, a lamination, an exposure, a development and/or an etching process may be used to form and pattern the magnetic layer 103. The magnetic layer 105 may be formed and coupled to the second surface of the dielectric layer 102. The magnetic layer 105 may be formed such that at least part of the plurality of interconnects 850 may be located in at least part of the magnetic layer 105. The magnetic layer 105 may include a plurality of openings. A deposition, a lamination, an exposure, a development and/or an etching process may be used to form and pattern the magnetic layer 105. The magnetic layer 105 may include the same, similar or different magnetic properties from the magnetic layer 103. Thus, the magnetic layer 105 may include the same, similar or different materials from the magnetic layer 103. In some implementations, instead of the magnetic layer 103 and/or the magnetic layer 105, a non-magnetic dielectric layer may be formed and patterned.

Stage 7, as shown in FIG. 8C, illustrates a plurality of interconnects 870 that are formed and coupled to a first surface (e.g., top surface) of the magnetic layer 103. The plurality of interconnects 870 are coupled to the plurality of interconnects 830. Stage 7 also illustrates a plurality of interconnects 890 that are formed and coupled to a second surface (e.g., bottom surface) of the magnetic layer 105. The plurality of interconnects 890 are coupled to the plurality of interconnects 850. A plating process and a patterning process may be used to form the plurality of interconnects 870 and/or the plurality of interconnects 890.

Stage 8 illustrates a state after a solder resist layer 107 is formed and patterned. The solder resist layer 107 may be coupled to the plurality of interconnects 870 and the magnetic layer 103. A deposition, a lamination, an exposure, a development and/or an etching process may be used to form and pattern the solder resist layer 107. Stage 8 also illustrates a state after a solder resist layer 109 is formed and patterned. The solder resist layer 109 may be coupled to the plurality of interconnects 890 and the magnetic layer 105. A deposition, a lamination, an exposure, a development and/or an etching process may be used to form and pattern the solder resist layer 109.

Stage 8 may illustrate a substrate 100 that includes several interconnects configured to operate as two or more inductors. For example, via interconnects from the plurality of via interconnects 120, interconnects from the plurality of interconnects 830, interconnects from the plurality of interconnects 850, interconnects from the plurality of interconnects 870 and/or interconnects from the plurality of interconnects 890 may define the inductor 140 and/or the inductor 142 of the substrate 100. The plurality of interconnects 830 and/or the plurality of interconnects 850 may represent the plurality of interconnects 130 and/or the plurality of interconnects 150. The plurality of interconnects 870 and/or the plurality of interconnects 890 may represent the plurality of interconnects 170 and/or the plurality of interconnects 190. In some implementations, a plurality of solder interconnects may be coupled to the substrate 100 through openings in the solder resist layer 107 and/or openings in the solder resist layer 109.

Once the substrate (e.g., 100, 200) is provided and/or fabricated, an integrated device (e.g., 403) may be coupled to the substrate through at least a plurality of solder interconnects (e.g., 430). The substrate and the integrated device may then be coupled to a board (e.g., 401) through a plurality of solder interconnects (e.g., 420).

### Exemplary Flow Diagram of a Method for Fabricating a Substrate With a Magnetic Layer

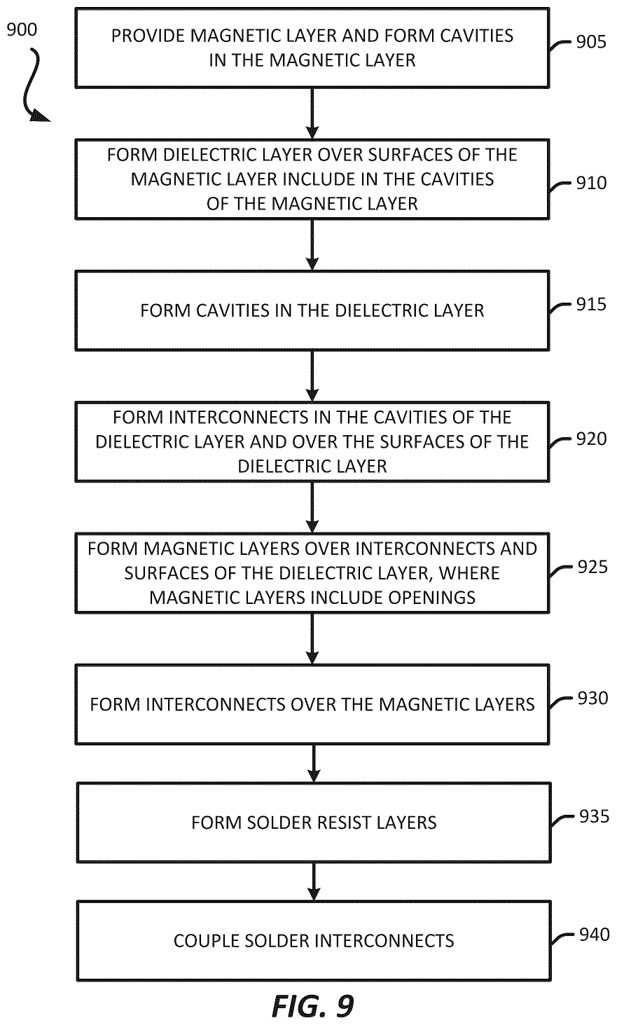

In some implementations, fabricating a substrate includes several processes. FIG. 9 illustrates an exemplary flow diagram of a method 900 for providing or fabricating a substrate. In some implementations, the method 900 of FIG. 9 may be used to provide or fabricate the substrate 100. The method 900 may be implemented on a wafer and then singulated into several substrates.

It should be noted that the method 900 of FIG. 9 may combine one or more processes in order to simplify and/or clarify the method for providing or fabricating a substrate. In some implementations, the order of the processes may be changed or modified.

The method provides (at 905) a magnetic layer and forms a plurality of cavities in the magnetic layer. Stage 1 of FIG. 8A, illustrates and describes an example of a state after a magnetic layer 101 is provided. Different implementations may provide different types of a magnetic layer. Stage 2 of FIG. 8A, illustrates and describes an example of a state after a plurality of cavities 800 are formed through the magnetic layer 101. A laser process (e.g., laser ablation process) may be used to form the plurality of cavities 800 in the magnetic layer 101. However, different implementations may use different processes to form the plurality of cavities 800. The plurality of cavities 800 may extend through the thickness of the magnetic layer 101.

The method forms (at 910) a dielectric layer in the cavities of the magnetic layer and couples the dielectric layer to surfaces of the magnetic layer. Stage 3 of FIG. 8A, illustrates and describes an example of a state after a dielectric layer 102 is formed. The dielectric layer 102 may be formed in the plurality of cavities 800 of the magnetic layer 101. The dielectric layer 102 may also be formed and coupled to (i) a first surface (e.g., top surface) of the magnetic layer 101 and/or (ii) a second surface (e.g., bottom surface) of the magnetic layer 101. A deposition process and/or a lamination process may be used to form the dielectric layer 102. In some implementations, the dielectric layer 102 may include a polymer. In some implementations, the dielectric layer 102 may include Ajinomoto Build-up Film (ABF).

The method forms (at 915) a plurality of cavities in the dielectric layer. Stage 4 of FIG. 8B, illustrates and describes an example of a state after a plurality of cavities 810 are formed through the dielectric layer 102. A laser process (e.g., laser ablation) may be used to form the plurality of cavities 810 in the dielectric layer 102. However, different implementations may use different processes to form the plurality of cavities 810. The plurality of cavities 810 may extend through the thickness of the dielectric layer 102.

The method forms (at 920) a plurality of via interconnects in the cavities of the dielectric layer and a plurality of interconnects on surfaces of the dielectric layer. Stage 5 of FIG. 8B, illustrates and describes an example of a state after a plurality of via interconnects 120 are formed in the plurality of cavities 810. The plurality of via interconnects 120 may considered to be located in the dielectric layer 102 and/or located in at least part of the plurality of cavities 800 of the magnetic layer 101. Stage 5 also illustrates a plurality of interconnects 830 that are formed and coupled to a first surface (e.g., top surface) of the dielectric layer 102. The plurality of interconnects 830 are coupled to the plurality of via interconnects 120. Stage 5 also illustrates a plurality of interconnects 850 that are formed and coupled to a second surface (e.g., bottom surface) of the dielectric layer 102. The plurality of interconnects 850 are coupled to the plurality of via interconnects 120. A plating process and a patterning process may be used to form the plurality of via interconnects 120, the plurality of interconnects 830 and/or the plurality of interconnects 850.

The method forms (at 925) magnetic layers that are coupled to the dielectric layer. Stage 6 of FIG. 8B, illustrates and describes an example of a state after the magnetic layer 103 and the magnetic layer 105 are formed. The magnetic layer 103 may be formed and coupled to the first surface of the dielectric layer 102. The magnetic layer 103 may be formed such that at least part of the plurality of interconnects 830 may be located in at least part of the magnetic layer 103. The magnetic layer 103 may include a plurality of openings. A deposition, a lamination, an exposure, a development and/or an etching process may be used to form and pattern the magnetic layer 103. The magnetic layer 105 may be formed and coupled to the second surface of the dielectric layer 102. The magnetic layer 105 may be formed such that at least part of the plurality of interconnects 850 may be located in at least part of the magnetic layer 105. The magnetic layer 105 may include a plurality of openings. A deposition, a lamination, an exposure, a development and/or an etching process may be used to form and pattern the magnetic layer 105. The magnetic layer 105 may include the same, similar or different magnetic properties from the magnetic layer 103. Thus, the magnetic layer 105 may include the same, similar or different materials from the magnetic layer 103. In some implementations, instead of the magnetic layer 103 and/or the magnetic layer 105, a non-magnetic dielectric layer may be formed and patterned (at 925).

The method forms (at 930) a plurality of interconnects on and/or over surfaces of the magnetic layers. Stage 7 of FIG. 8C, illustrates and describes an example of a plurality of interconnects 870 that are formed and coupled to a first surface (e.g., top surface) of the magnetic layer 103. The plurality of interconnects 870 are coupled to the plurality of interconnects 830. Stage 7 also illustrates and describes a plurality of interconnects 890 that are formed and coupled to a second surface (e.g., bottom surface) of the magnetic layer 105. The plurality of interconnects 890 are coupled to the plurality of interconnects 850. A plating process and a patterning process may be used to form the plurality of interconnects 870 and/or the plurality of interconnects 890.

The method forms (at 935) a plurality of solder resist layers. Stage 8 of FIG. 8C, illustrates and describes an example of a state after a solder resist layer 107 is formed and patterned. The solder resist layer 107 may be coupled to the plurality of interconnects 870 and the magnetic layer 103. A deposition, a lamination, an exposure, a development and/or an etching process may be used to form and pattern the solder resist layer 107. Stage 8 of FIG. 8C also illustrates and describes an example of a state after a solder resist layer 109 is formed and patterned. The solder resist layer 109 may be coupled to the plurality of interconnects 890 and the magnetic layer 105. A deposition, a lamination, an exposure, a development and/or an etching process may be used to form and pattern the solder resist layer 109.

Stage 8 of FIG. 8C, may illustrate a substrate 100 that includes several interconnects configured to operate as two or more inductors. For example, via interconnects from the plurality of via interconnects 120, interconnects from the plurality of interconnects 830, interconnects from the plurality of interconnects 850, interconnects from the plurality of interconnects 870 and/or interconnects from the plurality of interconnects 890 may define the inductor 140 and/or the inductor 142 of the substrate 100. The plurality of interconnects 830 and/or the plurality of interconnects 850 may represent the plurality of interconnects 130 and/or the plurality of interconnects 150. The plurality of interconnects 870 and/or the plurality of interconnects 890 may represent the plurality of interconnects 170 and/or the plurality of interconnects 190.

The method couples (at 940) a plurality of solder interconnects to interconnects of the substrate. In some implementations, a plurality of solder interconnects may be coupled to interconnects of the substrate 100 through openings in the solder resist layer 107 and/or openings in the solder resist layer 109.

### Exemplary Sequence for Fabricating a Substrate With a Magnetic Layer

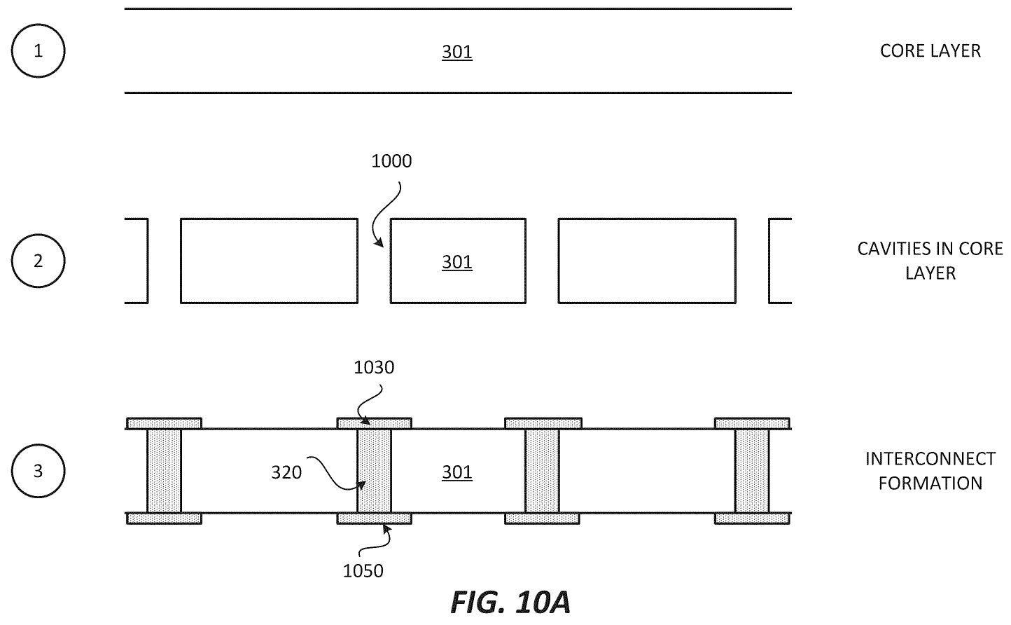

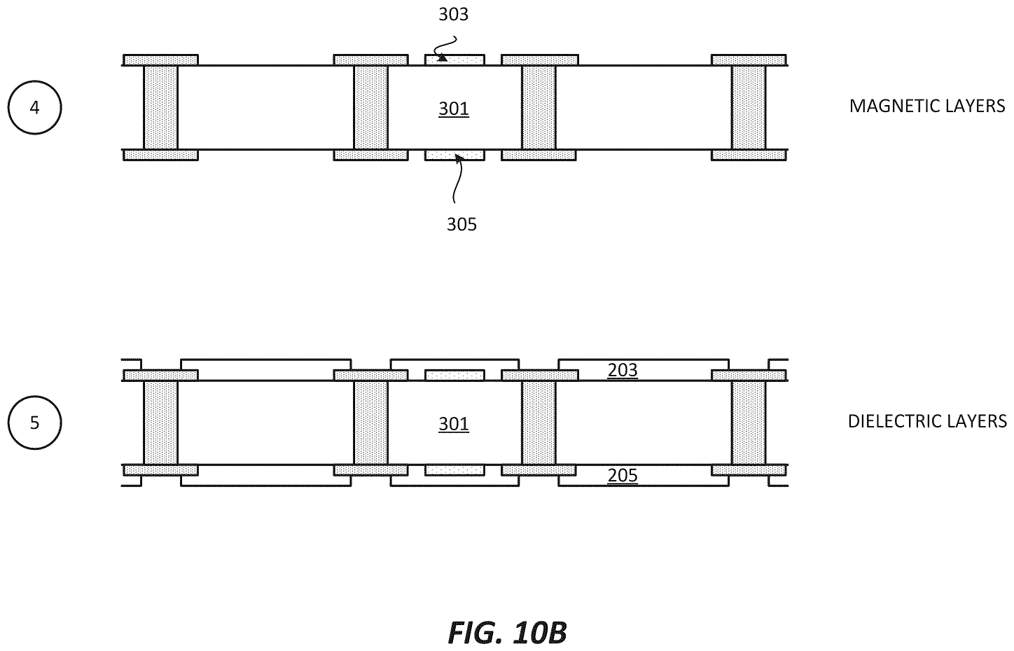

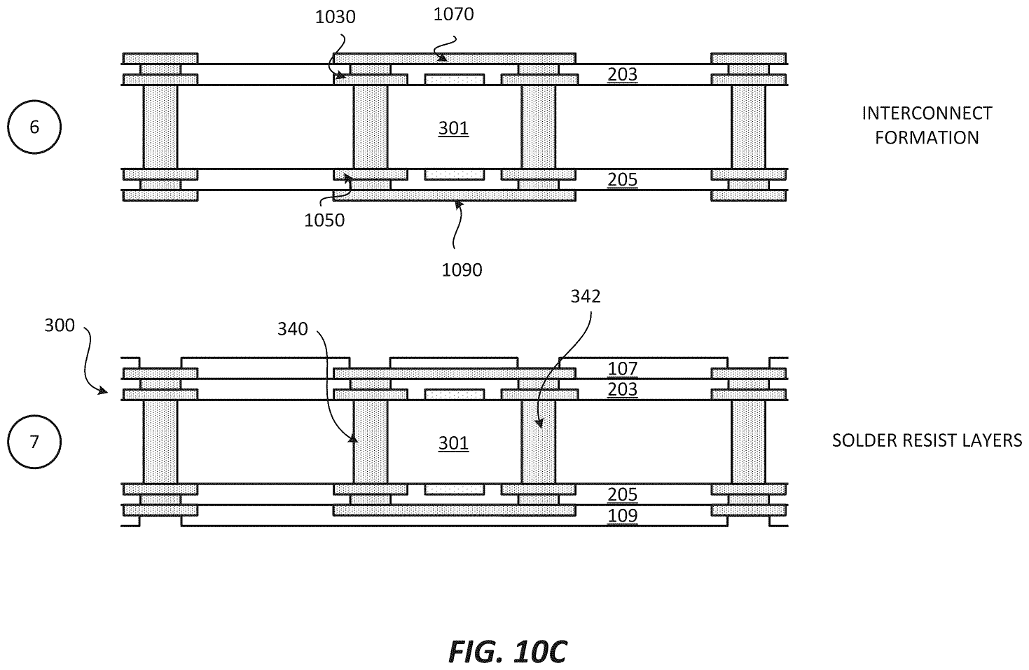

FIGS. 10A-10C illustrate an exemplary sequence for providing or fabricating a substrate with inductors and at least one magnetic layer. In some implementations, the sequence of FIGS. 10A-10C may be used to provide or fabricate any of the substrates described in the disclosure. In some implementations, the sequence of FIGS. 10A-10C may be used to provide or fabricate the substrate 300 described in the disclosure.

It should be noted that the sequence of FIGS. 10A-10C may combine one or more stages in order to simplify and/or clarify the sequence for providing or fabricating a substrate. In some implementations, the order of the processes may be changed or modified. In some implementations, one or more of processes may be replaced or substituted without departing from the spirit of the disclosure. Different implementations may fabricate a substrate differently.

Stage 1, as shown in FIG. 10A, illustrates a state after a core layer 301 is provided. Different implementations may provide different types of a core layer.

Stage 2 illustrates a state after a plurality of cavities 1000 are formed through the core layer 301. A laser process (e.g., laser ablation process) may be used to form the plurality of cavities 1000 in the core layer 301. However, different implementations may use different processes to form the plurality of cavities 1000. The plurality of cavities 1000 may extend through the thickness of the core layer 301.

Stage 3 illustrates a state after a plurality of via interconnects 320 are formed in the plurality of cavities 1000. Stage 3 also illustrates a plurality of interconnects 1030 that are formed and coupled to a first surface (e.g., top surface) of the core layer 301. The plurality of interconnects 1030 are coupled to the plurality of via interconnects 320. Stage 3 also illustrates a plurality of interconnects 1050 that are formed and coupled to a second surface (e.g., bottom surface) of the core layer 301. The plurality of interconnects 1050 are coupled to the plurality of via interconnects 320. A plating process and a patterning process may be used to form the plurality of via interconnects 320, the plurality of interconnects 1030 and/or the plurality of interconnects 1050.

Stage 4, as shown in FIG. 10B, illustrates a state after the magnetic layer 303 and the magnetic layer 305 are formed. The magnetic layer 303 may be formed and coupled to the first surface of the core layer 301. A deposition, a lamination, an exposure, a development and/or an etching process may be used to form and pattern the magnetic layer 303. The magnetic layer 305 may be formed and coupled to the second surface of the core layer 301. A deposition, a lamination, an exposure, a development and/or an etching process may be used to form and pattern the magnetic layer 305. The magnetic layer 305 may include the same, similar or different magnetic properties from the magnetic layer 303. Thus, the magnetic layer 305 may include the same, similar or different materials from the magnetic layer 303. The magnetic layer may include CZT (CoZrTa) material or Ajinomoto Magnetic Film (AMF).

Stage 5 illustrates a state after a dielectric layer 203 and the dielectric layer 205 are formed. The dielectric layer 203 may also be formed and coupled to (i) a first surface (e.g., top surface) of the core layer 301. The dielectric layer 203 may cover the magnetic layer 303 and/or the plurality of interconnects 1030. The dielectric layer 205 may also be formed and coupled to (i) a second surface (e.g., bottom surface) of the core layer 301. The dielectric layer 205 may cover the magnetic layer 305 and/or the plurality of interconnects 1050. A deposition process and/or a lamination process may be used to form the dielectric layer 203 and/or the dielectric layer 205. In some implementations, the dielectric layer 203 and/or the dielectric layer 205 may include a polymer. In some implementations, the dielectric layer 203 and/or the dielectric layer 205 may include Ajinomoto Build-up Film (ABF). In some implementations, the dielectric layer 203 and/or the dielectric layer 205 may include prepreg.

Stage 6, as shown in FIG. 10C, illustrates a plurality of interconnects 1070 that are formed and coupled to a first surface (e.g., top surface) of the dielectric layer 203. The plurality of interconnects 1070 are coupled to the plurality of interconnects 1030. Stage 6 also illustrates and describes a plurality of interconnects 1090 that are formed and coupled to a second surface (e.g., bottom surface) of the core layer 301. The plurality of interconnects 1090 are coupled to the plurality of interconnects 1050. A plating process and a patterning process may be used to form the plurality of interconnects 1070 and/or the plurality of interconnects 1090.

Stage 7, as shown in FIG. 10C illustrates a state after a solder resist layer 107 is formed and patterned. The solder resist layer 107 may be coupled to the plurality of interconnects 1070 and the dielectric layer 203. A deposition, a lamination, an exposure, a development and/or an etching process may be used to form and pattern the solder resist layer 107. Stage 7 also illustrates and describes a state after a solder resist layer 109 is formed and patterned. The solder resist layer 109 may be coupled to the plurality of interconnects 1090 and the dielectric layer 205. A deposition, a lamination, an exposure, a development and/or an etching process may be used to form and pattern the solder resist layer 109.

Stage 7 may illustrate a substrate 300 that includes several interconnects configured to operate as two or more inductors. For example, via interconnects from the plurality of via interconnects 320, interconnects from the plurality of interconnects 1030, interconnects from the plurality of interconnects 1050, interconnects from the plurality of interconnects 1070 and/or interconnects from the plurality of interconnects 1090 may define the inductor 340 and/or the inductor 342 of the substrate 300. The plurality of interconnects 1030 and/or the plurality of interconnects 1050 may represent the plurality of interconnects 130 and/or the plurality of interconnects 150. The plurality of interconnects 1070 and/or the plurality of interconnects 1090 may represent the plurality of interconnects 170 and/or the plurality of interconnects 190. In some implementations, a plurality of solder interconnects may be coupled to the substrate 300 through openings in the solder resist layer 107 and/or openings in the solder resist layer 109.

Once the substrate (e.g., 300) is provided and/or fabricated, an integrated device (e.g., 403) may be coupled to the substrate through at least a plurality of solder interconnects (e.g., 430). The substrate and the integrated device may then be coupled to a board (e.g., 401) through at least plurality of solder interconnects (e.g., 420).

### Exemplary Flow Diagram of a Method for Fabricating a Substrate With a Magnetic Layer

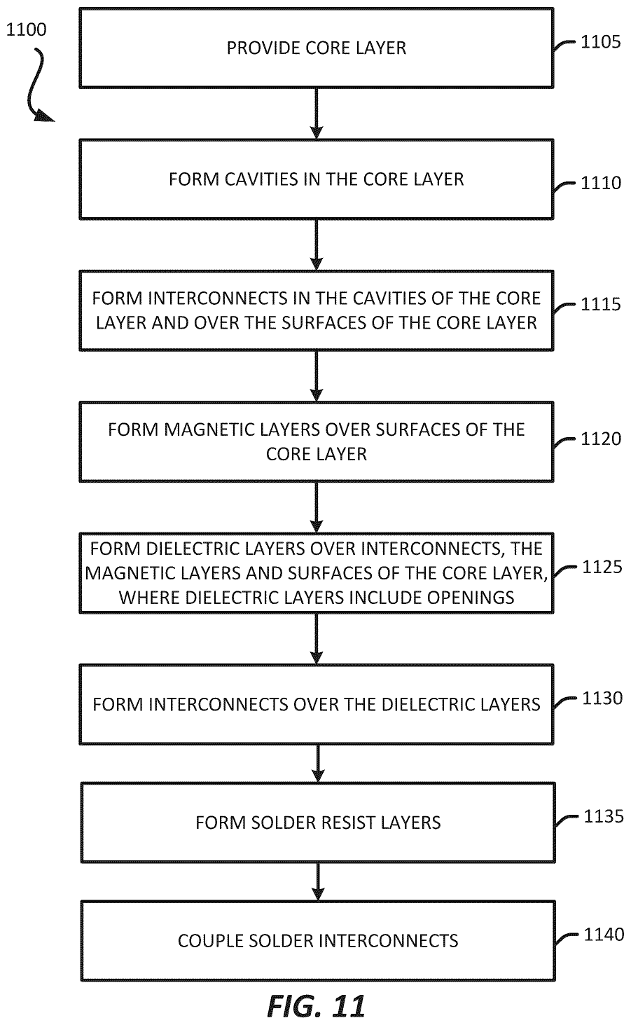

In some implementations, fabricating a substrate includes several processes. FIG. 11 illustrates an exemplary flow diagram of a method 1100 for providing or fabricating a substrate. In some implementations, the method 1100 of FIG. 11 may be used to provide or fabricate the substrate 300.

It should be noted that the method 1100 of FIG. 11 may combine one or more processes in order to simplify and/or clarify the method for providing or fabricating a substrate. In some implementations, the order of the processes may be changed or modified.

The method provides (at 1105) a core layer. Stage 1 of FIG. 10A, illustrates and describes an example of a state after a core layer 301 is provided. Different implementations may provide different types of a core layer.

The method forms (at 1110) a plurality of cavities in the core layer. Stage 2 of FIG. 10A, illustrates and describes an example of a state after a plurality of cavities 1000 are formed through the core layer 301. A laser process (e.g., laser ablation process) may be used to form the plurality of cavities 1000 in the core layer 301. However, different implementations may use different processes to form the plurality of cavities 1000. The plurality of cavities 1000 may extend through the thickness of the core layer 301.

The method forms (at 1115) via interconnects in the cavities of the core layer and on surfaces of the core layer. Stage 3 of FIG. 10A, illustrates and describes an example of a state after a plurality of via interconnects 320 are formed in the plurality of cavities 1000. Stage 3 also illustrates and describes a plurality of interconnects 1030 that are formed and coupled to a first surface (e.g., top surface) of the core layer 301. The plurality of interconnects 1030 are coupled to the plurality of via interconnects 320. Stage 3 also illustrates a plurality of interconnects 1050 that are formed and coupled to a second surface (e.g., bottom surface) of the core layer 301. The plurality of interconnects 1050 are coupled to the plurality of via interconnects 320. A plating process and a patterning process may be used to form the plurality of via interconnects 320, the plurality of interconnects 1030 and/or the plurality of interconnects 1050.

The method forms (at 1120) magnetic layers that are coupled to surfaces of the core layer. Stage 4 of FIG. 10B, illustrates and describes an example of a state after the magnetic layer 303 and the magnetic layer 305 that are formed. The magnetic layer 303 may be formed and coupled to the first surface of the core layer 301. A deposition, a lamination, an exposure, a development and/or an etching process may be used to form and pattern the magnetic layer 303. The magnetic layer 305 may be formed and coupled to the second surface of the core layer 301. A deposition, a lamination, an exposure, a development and/or an etching process may be used to form and pattern the magnetic layer 305. The magnetic layer 305 may include the same, similar or different magnetic properties from the magnetic layer 303. Thus, the magnetic layer 305 may include the same, similar or different materials from the magnetic layer 303.

The method forms (at 1125) dielectric layers that are coupled to the magnetic layers and/or the core layers. Stage 5 of FIG. 10B, illustrates and describes an example of a state after a dielectric layer 203 and the dielectric layer 205 are formed. The dielectric layer 203 may also be formed and coupled to (i) a first surface (e.g., top surface) of the core layer 301. The dielectric layer 203 may cover the magnetic layer 303 and/or the plurality of interconnects 1030. The dielectric layer 205 may also be formed and coupled to (i) a second surface (e.g., bottom surface) of the core layer 301. The dielectric layer 205 may cover the magnetic layer 305 and/or the plurality of interconnects 1050. A deposition process and/or a lamination process may be used to form the dielectric layer 203 and/or the dielectric layer 205. In some implementations, the dielectric layer 203 and/or the dielectric layer 205 may include a polymer. In some implementations, the dielectric layer 203 and/or the dielectric layer 205 may include ABF.

The method forms (at 1130) a plurality of interconnects. Stage 6 of FIG. 10C, illustrates and describes an example of a plurality of interconnects 1070 that are formed and coupled to a first surface (e.g., top surface) of the dielectric layer 203. The plurality of interconnects 1070 are coupled to the plurality of interconnects 1030. Stage 6 also illustrates a plurality of interconnects 1090 that are formed and coupled to a second surface (e.g., bottom surface) of the core layer 301. The plurality of interconnects 1090 are coupled to the plurality of interconnects 1050. A plating process and a patterning process may be used to form the plurality of interconnects 1070 and/or the plurality of interconnects 1090.

The method forms (at 1135) at least one solder resist layer. Stage 7 of FIG. 10C, illustrates and describes an example of a state after a solder resist layer 107 is formed and patterned. The solder resist layer 107 may be coupled to the plurality of interconnects 1070 and the dielectric layer 203. A deposition, a lamination, an exposure, a development and/or an etching process may be used to form and pattern the solder resist layer 107. Stage 7 also illustrates and describes an example of a state after a solder resist layer 109 is formed and patterned. The solder resist layer 109 may be coupled to the plurality of interconnects 1090 and the dielectric layer 205. A deposition, a lamination, an exposure, a development and/or an etching process may be used to form and pattern the solder resist layer 109.

Stage 7 may illustrate a substrate 300 that includes several interconnects configured to operate as two or more inductors. For example, via interconnects from the plurality of via interconnects 320, interconnects from the plurality of interconnects 1030, interconnects from the plurality of interconnects 1050, interconnects from the plurality of interconnects 1070 and/or interconnects from the plurality of interconnects 1090 may define the inductor 340 and/or the inductor 342 of the substrate 300. The plurality of interconnects 1030 and/or the plurality of interconnects 1050 may represent the plurality of interconnects 130 and/or the plurality of interconnects 150. The plurality of interconnects 1070 and/or the plurality of interconnects 1090 may represent the plurality of interconnects 170 and/or the plurality of interconnects 190. In some implementations, a plurality of solder interconnects may be coupled to the substrate 300 through openings in the solder resist layer 107 and/or openings in the solder resist layer 109.

The method couples (at 1140) a plurality of solder interconnects to interconnects of the substrate. In some implementations, a plurality of solder interconnects may be coupled to interconnects of the substrate 300 through openings in the solder resist layer 107 and/or openings in the solder resist layer 109.

Once the substrate (e.g., 300) is provided and/or fabricated, an integrated device (e.g., 403) may be coupled to the substrate through at least a plurality of solder interconnects (e.g., 430). The substrate and the integrated device may then be coupled to a board (e.g., 401) through a plurality of solder interconnects (e.g., 420).

### Exemplary Electronic Devices

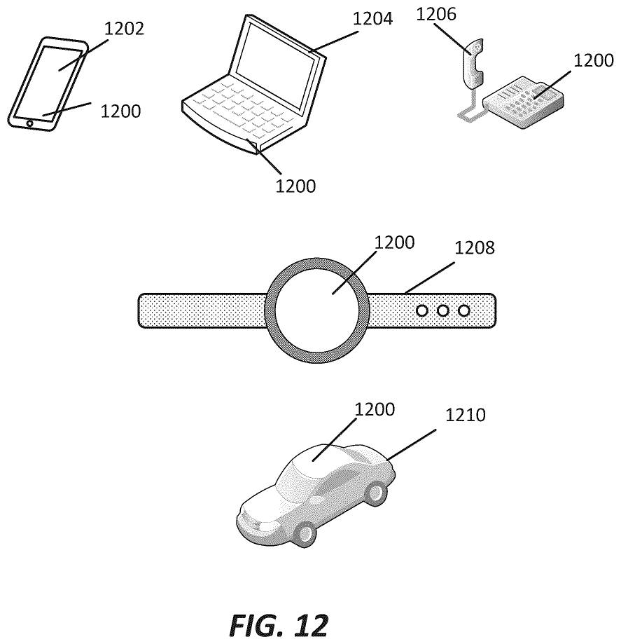

FIG. 12 illustrates various electronic devices that may be integrated with any of the aforementioned device, integrated device, integrated circuit (IC) package, integrated circuit (IC) device, semiconductor device, integrated circuit, die, interposer, package, package-on-package (POP), System in Package (SiP), or System on Chip (SoC). For example, a mobile phone device 1202, a laptop computer device 1204, a fixed location terminal device 1206, a wearable device 1208, or automotive vehicle 1210 may include a device 1200 as described herein. The device 1200 may be, for example, any of the devices and/or integrated circuit (IC) packages described herein. The devices 1202, 1204, 1206 and 1208 and the vehicle 1210 illustrated in FIG. 12 are merely exemplary. Other electronic devices may also feature the device 1200 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

One or more of the components, processes, features, and/or functions illustrated in FIGS. 1-7, 8A-8C, 9, 10A-10C, and/or 11-12 may be rearranged and/or combined into a single component, process, feature or function or embodied in several components, processes, or functions. Additional elements, components, processes, and/or functions may also be added without departing from the disclosure. It should also be noted FIGS. 1-7, 8A-8C, 9, 10A-10C, and/or 11-12 and its corresponding description in the present disclosure is not limited to dies and/or ICs. In some implementations, FIGS. 1-7, 8A-8C, 9, 10A-10C, and/or 11-12 and its corresponding description may be used to manufacture, create, provide, and/or produce devices and/or integrated devices. In some implementations, a device may include a die, an integrated device, an integrated passive device (IPD), a die package, an integrated circuit (IC) device, a device package, an integrated circuit (IC) package, a wafer, a semiconductor device, a package-on-package (POP) device, a heat dissipating device and/or an interposer.

It is noted that the figures in the disclosure may represent actual representations and/or conceptual representations of various parts, components, objects, devices, packages, integrated devices, integrated circuits, and/or transistors. In some instances, the figures may not be to scale. In some instances, for purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another-even if they do not directly physically touch each other. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first”, “second”, “third” and “fourth” (and/or anything above fourth) is arbitrary. Any of the components described may be the first component, the second component, the third component or the fourth component. For example, a component that is referred to a second component, may be the first component, the second component, the third component or the fourth component. The term “encapsulating” means that the object may partially encapsulate or completely encapsulate another object. A first component that is “located” in a second component may mean that the first component is “partially located” in the second component or “completely located” in the second component. A first component that is “embedded” in a second component may mean that the first component is “partially embedded” in the second component or “completely embedded” in the second component. The terms “top” and “bottom” are arbitrary. A component that is located on top may be located over a component that is located on a bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. The term “about ‘value X’”, or “approximately value X”, as used in the disclosure means within 10 percent of the ‘value X’. For example, a value of about 1 or approximately 1, would mean a value in a range of 0.9-1.1.

In some implementations, an interconnect is an element or component of a device or package that allows or facilitates an electrical connection between two points, elements and/or components. In some implementations, an interconnect may include a trace, a via, a pad, a pillar, a metallization layer, a redistribution layer, and/or an under bump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more metal layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the following, further examples are described to facilitate the understanding of the disclosure.

Aspect 1: A package comprising: an integrated device; and a substrate coupled to the integrated device through at least a plurality of solder interconnects, wherein the substrate comprises: at least one magnetic layer; at least one dielectric layer; and a plurality of interconnects, wherein the plurality of interconnects comprise: a first set of interconnects that are configured to operate as a first inductor; and a second set of interconnects that are configured to operate as a second inductor, wherein the second inductor and the first inductor are configured to operate as inductively coupled inductors.

Aspect 2: The package of aspect 1, wherein the first inductor is configured to induce a current in the second inductor.

Aspect 3: The package of aspects 1 through 2, wherein the first inductor is intertwined with the second inductor.

Aspect 4: The package of aspects 1 through 3, the at least one magnetic layer surrounds at least part of the first set of interconnects that define the first inductor and the second set of interconnects that define the second inductor.

Aspect 5: The package of aspects 1 through 4, wherein the at least one magnetic layer includes a first magnetic layer, wherein the at least one dielectric layer includes a first dielectric layer, a second dielectric layer and a third dielectric layer, wherein the first magnetic layer is located at least partially in the first dielectric layer, wherein the second dielectric layer is coupled to a first surface of the first dielectric layer, and wherein the third dielectric layer is coupled to a second surface of the first dielectric layer.

Aspect 6: The package of aspects 1 through 4, wherein the at least one magnetic layer includes a first magnetic layer, a second magnetic layer, and a third magnetic layer, wherein the at least one dielectric layer includes a first dielectric layer, a second dielectric layer and a third dielectric layer, wherein the first magnetic layer is located at least partially in the first dielectric layer, wherein the second dielectric layer is coupled to a first surface of the first dielectric layer, wherein the third dielectric layer is coupled to a second surface of the first dielectric layer, wherein the second magnetic layer is coupled to a surface of the second dielectric layer, and wherein the third magnetic layer is coupled to a surface of the third dielectric layer.

Aspect 7: The package of aspect 6, wherein the first magnetic layer, the second magnetic layer and the third magnetic layer have a same magnetic property.

Aspect 8: The package of aspect 6, wherein one or more magnetic layers from the first magnetic layer, the second magnetic layer and/or the third magnetic layer have a different magnetic property.

Aspect 9: The package of aspects 1 through 4, further comprising a core layer, wherein the at least one magnetic layer includes a first magnetic layer, a second magnetic layer, wherein the at least one dielectric layer includes a first dielectric layer and a second dielectric layer, wherein the first magnetic layer is coupled to a first surface of the core layer, wherein the second magnetic layer is coupled to a second surface of the core layer, wherein the first dielectric layer is coupled to the first surface of the core layer, and wherein the second dielectric layer is coupled to the second surface of the core layer.

Aspect 10: The package of aspects 1 through 9, wherein the integrated device includes a power management integrated circuit (PMIC).

Aspect 11: A substrate comprising: at least one magnetic layer; at least one dielectric layer; and a plurality of interconnects, wherein the plurality of interconnects comprise: a first set of interconnects that are configured to operate as a first inductor; and a second set of interconnects that are configured to operate as a second inductor, wherein the second inductor and the first inductor are configured to operate as inductively coupled inductors.

Aspect 12: The substrate of aspect 11, wherein the first inductor is configured to induce a current in the second inductor.

Aspect 13: The substrate of aspects 11 through 12, wherein the first inductor is intertwined with the second inductor.

Aspect 14: The substrate of aspects 11 through 13, the at least one magnetic layer surrounds at least part of the first set of interconnects that define the first inductor and the second set of interconnects that define the second inductor.

Aspect 15: The substrate of aspects 11 through 14, wherein the at least one magnetic layer includes a first magnetic layer, wherein the at least one dielectric layer includes a first dielectric layer, a second dielectric layer and a third dielectric layer, wherein the first magnetic layer is located at least partially in the first dielectric layer, wherein the second dielectric layer is coupled to a first surface of the first dielectric layer, and wherein the third dielectric layer is coupled to a second surface of the first dielectric layer.

Aspect 16: The substrate of aspects 11 through 14, wherein the at least one magnetic layer includes a first magnetic layer, a second magnetic layer, and a third magnetic layer, wherein the at least one dielectric layer includes a first dielectric layer, a second dielectric layer and a third dielectric layer, wherein the first magnetic layer is located at least partially in the first dielectric layer, wherein the second dielectric layer is coupled to a first surface of the first dielectric layer, wherein the third dielectric layer is coupled to a second surface of the first dielectric layer, wherein the second magnetic layer is coupled to a surface of the second dielectric layer, and wherein the third magnetic layer is coupled to a surface of the third dielectric layer.

Aspect 17: The substrate of aspect 16, wherein the first magnetic layer, the second magnetic layer and the third magnetic layer have the same magnetic property.

Aspect 18: The substrate of aspect 16, wherein one or more magnetic layers from the first magnetic layer, the second magnetic layer and/or the third magnetic layer have a different magnetic property.

Aspect 19: The substrate of aspects 11 through 14, further comprising a core layer, wherein the at least one magnetic layer includes a first magnetic layer, a second magnetic layer, wherein the at least one dielectric layer includes a first dielectric layer and a second dielectric layer, wherein the first magnetic layer is coupled to a first surface of the core layer, wherein the second magnetic layer is coupled to a second surface of the core layer, wherein the first dielectric layer is coupled to the first surface of the core layer, and wherein the second dielectric layer is coupled to the second surface of the core layer.

Aspect 20: The substrate of aspects 11 through 19, wherein the first inductor includes a first solenoid inductor, wherein the second inductor includes a second solenoid inductor, and wherein the first solenoid inductor is intertwined with the second solenoid inductor.

Aspect 21: A method for fabricating a substrate, comprising: providing at least one magnetic layer; providing at least one dielectric layer; and forming a plurality of interconnects, wherein the plurality of interconnects comprise: a first set of interconnects that are configured to operate as a first inductor; and a second set of interconnects that are configured to operate as a second inductor, wherein the second inductor and the first inductor are configured to operate as inductively coupled inductors.

Aspect 22: The method of aspect 21, the at least one magnetic layer surrounds at least part of the first set of interconnects that define the first inductor and the second set of interconnects that define the second inductor.

Aspect 23: The method of aspects 21 through 22, wherein the at least one magnetic layer includes a first magnetic layer, wherein the at least one dielectric layer includes a first dielectric layer, a second dielectric layer and a third dielectric layer, wherein the first magnetic layer is located at least partially in the first dielectric layer, wherein the second dielectric layer is coupled to a first surface of the first dielectric layer, and wherein the third dielectric layer is coupled to a second surface of the first dielectric layer.

Aspect 24: The method of aspects 21 through 22, wherein the at least one magnetic layer includes a first magnetic layer, a second magnetic layer, and a third magnetic layer, wherein the at least one dielectric layer includes a first dielectric layer, a second dielectric layer and a third dielectric layer, wherein the first magnetic layer is located at least partially in the first dielectric layer, wherein the second dielectric layer is coupled to a first surface of the first dielectric layer, wherein the third dielectric layer is coupled to a second surface of the first dielectric layer, wherein the second magnetic layer is coupled to a surface of the second dielectric layer, and wherein the third magnetic layer is coupled to a surface of the third dielectric layer.

Aspect 25: The method of aspects 21 through 22, further comprising providing a core layer, wherein the at least one magnetic layer includes a first magnetic layer, a second magnetic layer, wherein the at least one dielectric layer includes a first dielectric layer and a second dielectric layer, wherein the first magnetic layer is coupled to a first surface of the core layer, wherein the second magnetic layer is coupled to a second surface of the core layer, wherein the first dielectric layer is coupled to the first surface of the core layer, and wherein the second dielectric layer is coupled to the second surface of the core layer.

Aspect 26: A method for fabricating a package. The method provides a substrate comprising: at least one magnetic layer; at least one dielectric layer; and a plurality of interconnects, wherein the plurality of interconnects comprise: a first set of interconnects that are configured to operate as a first inductor; and a second set of interconnects that are configured to operate as a second inductor, wherein the second inductor and the first inductor are configured to operate as inductively coupled inductors. The method couples an integrated device to the substrate through at least a plurality of solder interconnects.

Aspect 27: The method of aspect 26, the at least one magnetic layer surrounds at least part of the first set of interconnects that define the first inductor and the second set of interconnects that define the second inductor.

Aspect 28: The method of aspects 26 through 27, wherein the at least one magnetic layer includes a first magnetic layer, wherein the at least one dielectric layer includes a first dielectric layer, a second dielectric layer and a third dielectric layer, wherein the first magnetic layer is located at least partially in the first dielectric layer, wherein the second dielectric layer is coupled to a first surface of the first dielectric layer, and wherein the third dielectric layer is coupled to a second surface of the first dielectric layer.

Aspect 29: The method of aspects 26 through 27, wherein the at least one magnetic layer includes a first magnetic layer, a second magnetic layer, and a third magnetic layer, wherein the at least one dielectric layer includes a first dielectric layer, a second dielectric layer and a third dielectric layer, wherein the first magnetic layer is located at least partially in the first dielectric layer, wherein the second dielectric layer is coupled to a first surface of the first dielectric layer, wherein the third dielectric layer is coupled to a second surface of the first dielectric layer, wherein the second magnetic layer is coupled to a surface of the second dielectric layer, and wherein the third magnetic layer is coupled to a surface of the third dielectric layer.

Aspect 30: The method of aspects 26 through 27, wherein the substrate further comprises a core layer, wherein the at least one magnetic layer includes a first magnetic layer, a second magnetic layer, wherein the at least one dielectric layer includes a first dielectric layer and a second dielectric layer, wherein the first magnetic layer is coupled to a first surface of the core layer, wherein the second magnetic layer is coupled to a second surface of the core layer, wherein the first dielectric layer is coupled to the first surface of the core layer, and wherein the second dielectric layer is coupled to the second surface of the core layer.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

1. A package comprising:
an integrated device; and
a substrate coupled to the integrated device through at least a plurality of solder interconnects, wherein the substrate comprises:
at least one magnetic layer;
at least one dielectric layer; and
a plurality of interconnects, wherein the plurality of interconnects comprise:
a first set of interconnects that are configured to operate as a first inductor; and
a second set of interconnects that are configured to operate as a second inductor, wherein the second inductor and the first inductor are configured to operate as inductively coupled inductors.

2. The package of claim 1, wherein the first inductor is configured to induce a current in the second inductor.

3. The package of claim 1, wherein the first inductor is intertwined with the second inductor.

4. The package of claim 1, the at least one magnetic layer surrounds at least part of the first set of interconnects that define the first inductor and the second set of interconnects that define the second inductor.

5. The package of claim 1,
wherein the at least one magnetic layer includes a first magnetic layer,
wherein the at least one dielectric layer includes a first dielectric layer, a second dielectric layer and a third dielectric layer,
wherein the first magnetic layer is located at least partially in the first dielectric layer,
wherein the second dielectric layer is coupled to a first surface of the first dielectric layer, and
wherein the third dielectric layer is coupled to a second surface of the first dielectric layer.

6. The package of claim 1,
wherein the at least one magnetic layer includes a first magnetic layer, a second magnetic layer, and a third magnetic layer,
wherein the at least one dielectric layer includes a first dielectric layer, a second dielectric layer and a third dielectric layer,
wherein the first magnetic layer is located at least partially in the first dielectric layer,
wherein the second dielectric layer is coupled to a first surface of the first dielectric layer,
wherein the third dielectric layer is coupled to a second surface of the first dielectric layer,
wherein the second magnetic layer is coupled to a surface of the second dielectric layer, and
wherein the third magnetic layer is coupled to a surface of the third dielectric layer.

7. The package of claim 6, wherein the first magnetic layer, the second magnetic layer and the third magnetic layer have a same magnetic property.

8. The package of claim 6, wherein one or more magnetic layers from the first magnetic layer, the second magnetic layer and/or the third magnetic layer have a different magnetic property.

9. The package of claim 1, further comprising a core layer,
wherein the at least one magnetic layer includes a first magnetic layer, a second magnetic layer,
wherein the at least one dielectric layer includes a first dielectric layer and a second dielectric layer,
wherein the first magnetic layer is coupled to a first surface of the core layer,
wherein the second magnetic layer is coupled to a second surface of the core layer,
wherein the first dielectric layer is coupled to the first surface of the core layer, and
wherein the second dielectric layer is coupled to the second surface of the core layer.

10. The package of claim 1, wherein the integrated device includes a power management integrated circuit (PMIC).

11. A substrate comprising:
at least one magnetic layer;
at least one dielectric layer; and
a plurality of interconnects, wherein the plurality of interconnects comprise:
a first set of interconnects that are configured to operate as a first inductor; and
a second set of interconnects that are configured to operate as a second inductor, wherein the second inductor and the first inductor are configured to operate as inductively coupled inductors.

12. The substrate of claim 11, wherein the first inductor is configured to induce a current in the second inductor.

13. The substrate of claim 11, wherein the first inductor is intertwined with the second inductor.

14. The substrate of claim 11, the at least one magnetic layer surrounds at least part of the first set of interconnects that define the first inductor and the second set of interconnects that define the second inductor.

15. The substrate of claim 11,
wherein the at least one magnetic layer includes a first magnetic layer,
wherein the at least one dielectric layer includes a first dielectric layer, a second dielectric layer and a third dielectric layer,
wherein the first magnetic layer is located at least partially in the first dielectric layer,
wherein the second dielectric layer is coupled to a first surface of the first dielectric layer, and
wherein the third dielectric layer is coupled to a second surface of the first dielectric layer.

16. The substrate of claim 11,
wherein the at least one magnetic layer includes a first magnetic layer, a second magnetic layer, and a third magnetic layer,
wherein the at least one dielectric layer includes a first dielectric layer, a second dielectric layer and a third dielectric layer,
wherein the first magnetic layer is located at least partially in the first dielectric layer,
wherein the second dielectric layer is coupled to a first surface of the first dielectric layer,
wherein the third dielectric layer is coupled to a second surface of the first dielectric layer,
wherein the second magnetic layer is coupled to a surface of the second dielectric layer, and
wherein the third magnetic layer is coupled to a surface of the third dielectric layer.

17. The substrate of claim 16, wherein the first magnetic layer, the second magnetic layer and the third magnetic layer have the same magnetic property.

18. The substrate of claim 16, wherein one or more magnetic layers from the first magnetic layer, the second magnetic layer and/or the third magnetic layer have a different magnetic property.

19. The substrate of claim 11, further comprising a core layer,
wherein the at least one magnetic layer includes a first magnetic layer, a second magnetic layer,
wherein the at least one dielectric layer includes a first dielectric layer and a second dielectric layer,
wherein the first magnetic layer is coupled to a first surface of the core layer,
wherein the second magnetic layer is coupled to a second surface of the core layer,
wherein the first dielectric layer is coupled to the first surface of the core layer, and
wherein the second dielectric layer is coupled to the second surface of the core layer.

20. The substrate of claim 11,
wherein the first inductor includes a first solenoid inductor,
wherein the second inductor includes a second solenoid inductor, and
wherein the first solenoid inductor is intertwined with the second solenoid inductor.

21. A method for fabricating a substrate, comprising:
providing at least one magnetic layer;
providing at least one dielectric layer; and
forming a plurality of interconnects, wherein the plurality of interconnects comprise:
a first set of interconnects that are configured to operate as a first inductor; and
a second set of interconnects that are configured to operate as a second inductor, wherein the second inductor and the first inductor are configured to operate as inductively coupled inductors.

22. The method of claim 21, the at least one magnetic layer surrounds at least part of the first set of interconnects that define the first inductor and the second set of interconnects that define the second inductor.

23. The method of claim 21,
wherein the at least one magnetic layer includes a first magnetic layer,
wherein the at least one dielectric layer includes a first dielectric layer, a second dielectric layer and a third dielectric layer,
wherein the first magnetic layer is located at least partially in the first dielectric layer,
wherein the second dielectric layer is coupled to a first surface of the first dielectric layer, and
wherein the third dielectric layer is coupled to a second surface of the first dielectric layer.

24. The method of claim 21,
wherein the at least one magnetic layer includes a first magnetic layer, a second magnetic layer, and a third magnetic layer,
wherein the at least one dielectric layer includes a first dielectric layer, a second dielectric layer and a third dielectric layer,
wherein the first magnetic layer is located at least partially in the first dielectric layer,
wherein the second dielectric layer is coupled to a first surface of the first dielectric layer,
wherein the third dielectric layer is coupled to a second surface of the first dielectric layer,
wherein the second magnetic layer is coupled to a surface of the second dielectric layer, and
wherein the third magnetic layer is coupled to a surface of the third dielectric layer.

25. The method of claim 21, further comprising providing a core layer,
wherein the at least one magnetic layer includes a first magnetic layer, a second magnetic layer,
wherein the at least one dielectric layer includes a first dielectric layer and a second dielectric layer,
wherein the first magnetic layer is coupled to a first surface of the core layer,
wherein the second magnetic layer is coupled to a second surface of the core layer,
wherein the first dielectric layer is coupled to the first surface of the core layer, and
wherein the second dielectric layer is coupled to the second surface of the core layer.
